(19) United States
(12) Patent Application Publication
(10) Pub. No.: US 2005/0063216 A1
(43) Pub. Date: Mar. 24, 2005

(54) System and method for providing efficient redundancy mirroring communications in an n-way scalable network storage system

(76) Inventors: Virgil V. Wilkins, Perris, CA (US); Robert L. Horn, Yorba Linda, CA (US)

Correspondence Address: DICKSTEIN SHAPIRO MORIN & OSHINSKY LLP, 2101 L Street, NW, Washington, DC, 20037, US

(21) Appl. No.: 10/947,216

(22) Filed: Sep. 23, 2004

Related U.S. Application Data
(60) Provisional application No. 60/505,021, filed on Sep. 24, 2003.

(51) Int. Cl. G11C 11/00

(52) U.S. Cl. 365/154

(57) ABSTRACT

A networked storage system controller architecture is capable of n-way distributed data redundancy using dynamically first-time allocated mirrored caches. Each storage controller has a cache mirror partition that may be used to mirror data in any other storage controller's dirty cache. As a storage controller receives a write request for a given volume it determines the owning storage controller for that volume. If another storage controller owns the volume requested, the receiving storage controller forwards the request to the owning storage controller. If no mirror has been previously established, the forwarding storage controller becomes the mirror. Thus, as data is received from the host, the receiving storage controller stores the data into its mirrored cache partition and copies the data to the owning storage controller.

This application claims the benefit of U.S. Provisional Application Ser. No. 60/505,021, filed Sep. 24, 2003.

### FIELD OF INVENTION

The present invention relates to cache mirroring in a networked storage controller system architecture.

### BACKGROUND OF THE INVENTION

The need for faster communication among computers and data storage systems requires ever faster and more efficient storage networks. In recent years, implementation of clustering techniques and storage area networks (SANs) has greatly improved storage network performance. In a typical storage network, for example, a number of servers are clustered together for a proportional performance gain, and a SAN fabric (e.g., a fiber channel-based SAN) is established between the servers and various redundant array of independent disks (RAID) storage systems/arrays. The SAN allows any server to access any storage element. However, in the typical storage network, each physical storage element has an associated storage controller that must be accessed in order to access data stored on that particular storage system. This can lead to bottlenecks in system performance as the storage managed by a particular storage controller may only be accessed through that storage controller. Furthermore, if a controller fails, information maintained in the storage system managed by the failed controller becomes inaccessible.

FIG. 1 is a conventional two-way redundant storage controller system 100. Storage controller system 100 includes a storage controller 1 (SC1) 110 and a storage controller 2 (SC2) 120, both of which are storage controller pairs. SC1 110 further includes a dirty cache partition 1 (DC1) 130 and a mirrored cache partition 2 (MC2) 140. SC1 110 controls a storage element 155, upon which a volume 1 150 resides. SC2 120 further includes a mirror cache partition 1 (MC1) 160, and a dirty cache partition 2 (DC2) 170. SC2 120 is coupled to SC1 110 via an inter-controller transfer 165. SC2 120 receives host commands through a host port (H2) 180 from a host 1 190. SC1 110 also includes a host port (H1) 181. Because SC1 110 and SC2 120 are storage controller pairs, the data stored in DC1 130 of SC1 110 is mirrored in MC1 160 of SC2 120. Likewise, the data stored in DC2 170 of SC2 120 is mirrored in MC2 140 of SC1 110.

In a cached write operation, a host requests a write to a particular volume. For example, host 1 190 requests a write to volume 1 150. Host 1 190 may request on H2 180, which is owned by SC2 120. SC2 120 is configured to know that volume 1 150 is controlled by SC1 110 through a configuration control process (not described). SC2 120 forwards the request to SC1 110 via inter-controller transfer 165. SC1 110 then allocates buffer memory for the incoming data and acknowledges to SC2 120 that it is ready to receive the write data. SC2 120 then receives the data from host 1 190 and stores the data in MC1 160. The data is now safely stored in SC2 120 on MC1 160. If SC1 110 should fail, the data is still recoverable and can be written to volume 1 150 at a later time. SC2 120 then copies the data to SC1 110 via inter-controller transfer 165. SC1 110 stores the write data to DC1 130 and acknowledges the write operation as complete to SC2 120. The data is now successfully mirrored in two separate locations, namely DC1 130 of SC1 110 and MC1 160 of SC2 120. If either controller should fail, the data is recoverable. SC2 120 then informs host 1 190 that the write operation is complete. At some point, DC1 130 reaches a dirty cache threshold limit set for SC1 110, and SC1 110 flushes the dirty cache stored data from DC1 130 to volume 1 150. The above described process is described in greater detail below in connection with FIG. 2.

FIG. 2 is a flow chart illustrating how a data write request to a volume is mirrored in the redundant controller's cache in the storage controller system 100 of FIG. 1. The following is a method 200 that shows the process steps for a cached write operation from host 1 190 to volume 1 150.

Step 210:

Issuing Write Command for Volume 1 on SC2

In this step, host 1 190 issues a write command via H2 180 to SC2 120 for volume 1 150. Method 200 proceeds to step 220.

Step 220:

Forwarding Write Command to SC1

In this step, SC2 120 forwards the write command to SC1 110 via inter-controller transfer 165. Method 200 proceeds to step 230.

Step 230:

Allocating Buffer Space for Write Data

In this step, SC1 110 allocates buffer space to accept the write data from host 1 190. Method 200 proceeds to step 240.

Step 240:

Acknowledging Write Request to SC2

In this step, SC1 110 acknowledges to SC2 120 that it has allocated buffer space for the incoming data and that it is ready to accept the data for a write operation. Method 200 proceeds to step 250.

Step 250:

Accepting Write Data from Host 1

In this step, SC2 120 accepts the write data from host 1 190 and stores the write data in MC1 160. Method 200 proceeds to step 260.

Step 260:

Copying Write Data to SC1

In this step, SC2 120 copies the write data received in step 250 to SC1 110 via inter-controller transfer 165. Method 200 proceeds to step 270.

Step 270:

Storing Write Data in Cache

In this step, SC1 110 stores the write data in DC1 130. Method 200 proceeds to step 280.

Step 280:

Acknowledging Write Operation Complete to SC2

In this step, SC1 110 acknowledges to SC2 120 that it received the write data and has the write data stored in cache. Method 200 proceeds to step 290.

Step 290:

Completing Write Command to Host 1

In this step, SC2 120 sends a write complete command to host 1 190, thus completing the cached write procedure and ending method 200.

If, for example, SC2 120 is busy during the request from host 1 190, host 1 190 has no other choice but to wait for SC2 120 to finish its current process and then request another write to volume 1 150. This is because SC2 120 mirrors the data from DC1 130 of SC1 110 into its own mirrored cache MC1 160. Because the mirrored caches correspond to the dirty cache on one and only one storage controller, there is an inherent bottleneck in the system when that one storage controller happens to be busy.

One method for achieving greater performance and greater reliability is to increase the number of storage controllers. However, in conventional redundant cached storage controller systems, the system may only be scaled by adding controllers in pairs because one controller has the mirrored cache for the other controller and vice-versa. If only one cached storage controller is required to improve system performance in a given system, two controllers must still be added. This inherently limits the ability to affordably scale a networked storage system. Adding two controllers to a system that only requires one more controller is inefficient and expensive. Another drawback to a two-way redundant controller architecture is that two-way redundancy may limit controller interconnect bandwidth. For example, in an any-host-to-any-volume scalable system, the same write data may pass through the interconnect two times. The first time, the data passes through the interconnect to the controller that owns the requested volume. The data may then pass back through the same interconnect to the yet another controller to be mirrored into that controller's cache.

U.S. Pat. No. 6,381,674, entitled, “Method and Apparatus for Providing Centralized Intelligent Cache between Multiple Data Controlling Elements,” describes an apparatus and methods that allow multiple storage controllers sharing access to common data storage devices in a data storage subsystem to access a centralized intelligent cache. The intelligent central cache provides substantial processing for storage management functions. In particular, the central cache described in the '674 patent performs RAID management functions on behalf of the plurality of storage controllers including, for example, redundancy information (parity) generation and checking, as well as RAID geometry (striping) management. The plurality of storage controllers transmit cache requests to the central cache controller. The central cache controller performs all operations related to storing supplied data in cache memory as well as posting such cached data to the storage array as required. The storage controllers are significantly simplified because the central cache obviates the need for duplicative local cache memory on each of the plurality of storage controllers, and thus the need for inter-controller communication for purposes of synchronizing local cache contents of the storage controllers. The storage subsystem of the '674 patent offers improved scalability in that the storage controllers are simplified as compared to those of prior designs. Addition of storage controllers to enhance subsystem performance is less costly than prior designs. The central cache controller may include a mirrored cache controller to enhance redundancy of the central cache controller. Communication between the cache controller and its mirror are performed over a dedicated communication link.

Unfortunately, the central cache described in the '674 patent creates a system bottleneck. A cache may only process a given number of transactions. When that number is exceeded, transactions begin to queue while waiting for access to the cache, and system throughput is hindered due to the cache bottleneck. Another drawback to the system described in the '674 patent is that excess communication links are required to perform the mirroring function. Extra links translates to extra hardware and extra overhead, which ultimately leads to extra cost. Finally, the system described in the '674 patent does not provide enough system flexibility such that any storage controller may mirror data to any other storage controller in the system. It is still a two-way redundant architecture between the central cache controller and the mirrored cache controller.

Therefore, it is an object of the present invention to provide redundancy in an n-way scalable networked storage system.

### SUMMARY OF THE INVENTION

The present invention is a networked storage system controller architecture that is capable of n-way distributed data redundancy using dynamically first-time allocated mirrored caches. Each storage controller has a cache mirror partition that may be used to mirror data in any other storage controller's dirty cache. As a storage controller receives a write request for a given volume it determines the owning storage controller for that volume. If another storage controller owns the volume requested, the receiving storage controller forwards the request to the owning storage controller. If no mirror has been previously established, the forwarding storage controller becomes the mirror. Thus, as data is received from the host, the receiving storage controller stores the data into its mirrored cache partition and copies the data to the owning storage controller. The method eliminates some of the need for the write data to pass across the interconnect more than once in order to be mirrored. This architecture presents a better level of scalability in that storage controllers may be added individually to the system as needed and need not be added in pairs. This architecture also provides a method for cache mirroring with reduced interconnect usage and reduced cache bottleneck issues, which ultimately provides better system performance.

### BRIEF DESCRIPTION OF THE DRAWINGS

The foregoing and other advantages and features of the invention will become more apparent from the detailed description of exemplary embodiments of the invention given below with reference to the accompanying drawings, in which:

FIG. 1 shows a block diagram of a conventional two-way redundant storage controller system architecture;

FIG. 2 is a flow diagram of the method for a cached write for use with the conventional two-way redundant storage controller system architecture of FIG. 1;

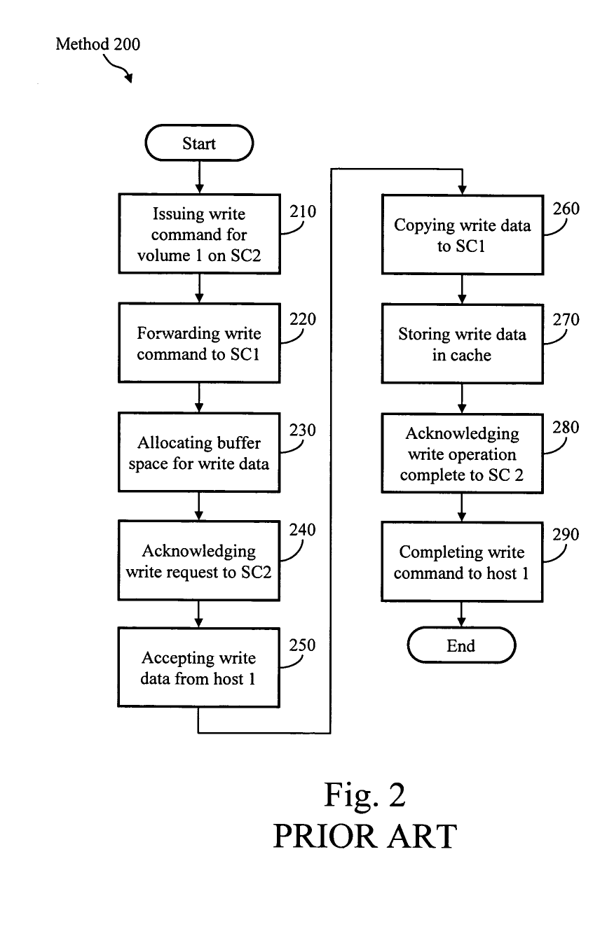

FIG. 3 shows an n-way distributed redundancy scalable networked storage controller architecture; and

FIG. 4 is a flow diagram of a method for performing a cached write operation for use with the n-way redundant storage controller system architecture of FIG. 3.

### DETAILED DESCRIPTION OF THE INVENTION

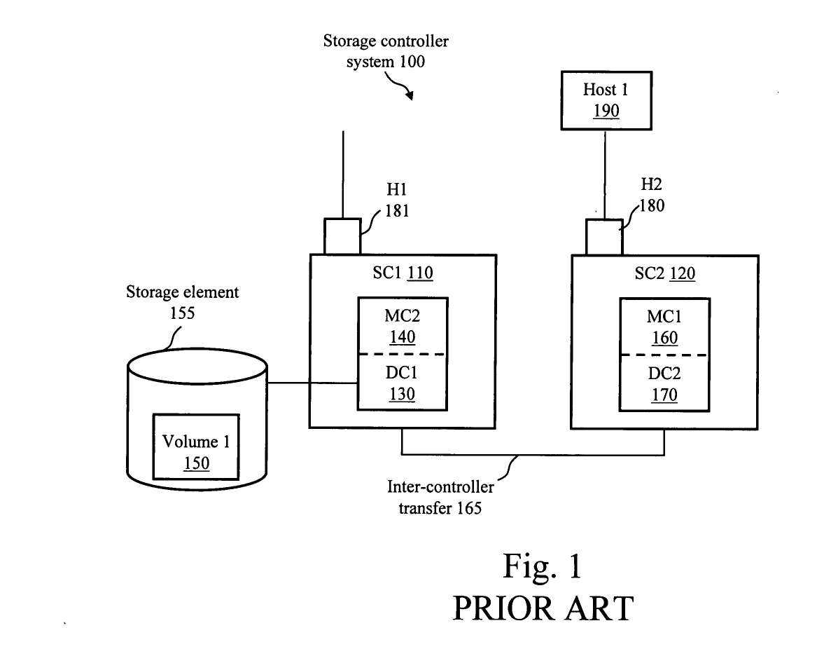

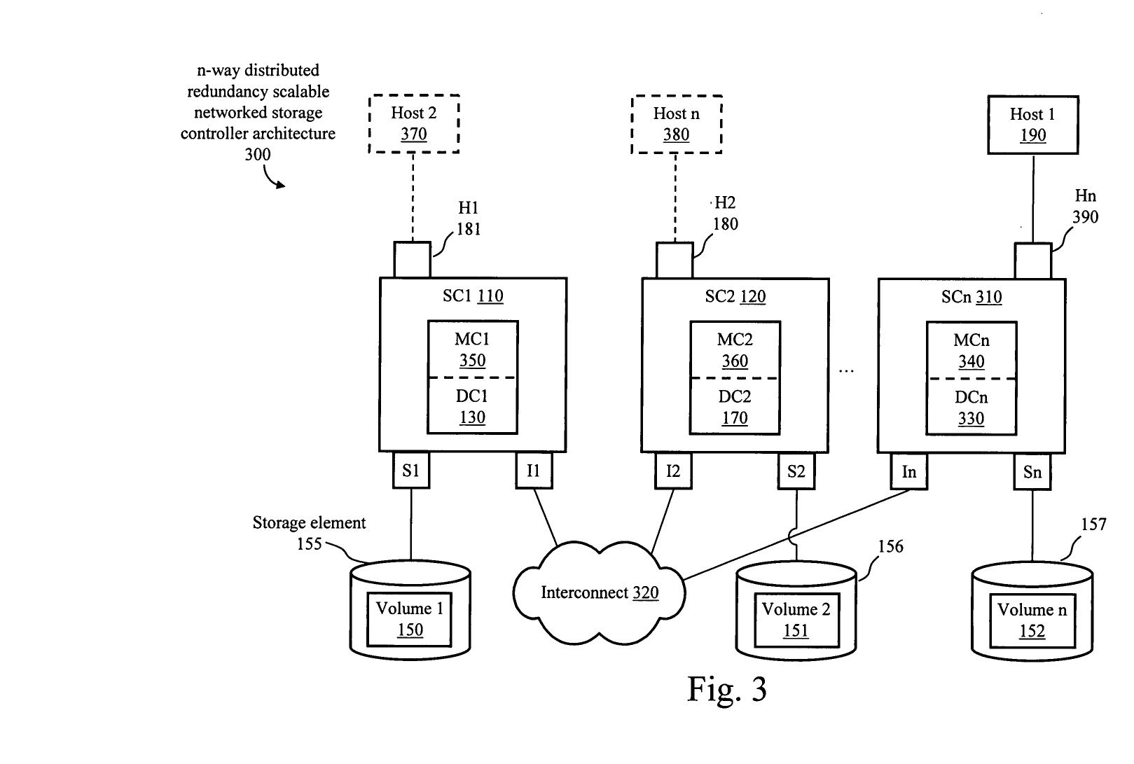

Now referring to FIG. 3, where like reference numerals designate like elements with FIG. 1, a block diagram of a n-way distributed redundancy scalable network storage controller architecture 300 is shown. Architecture 300 includes three storage controllers SC1 110, SC2 120, and SCn 310. In general, “n” is used herein to indicate an indefinite plurality, so that the number “n” when referred to one component does not necessarily equal the number “n” of a different component. However, it should be recognized that the invention may be practiced while varying the number of storage controllers.

Each storage controller includes a cache memory partitioned into a dirty cache partition and a mirror cache partition. For example, storage controllers SC1, SC2, SCn respectively include dirty cache partitions DC1 130, DC2 170, DCn 330 and mirror cache partitions MC1, MC2, and MCn. Each storage controller also includes a storage port for coupling to a storage element, an interconnect port for coupling to an interconnect coupling each storage controller, and a host port for coupling to one or more hosts. For example, storage controllers SC1, SC2, SCn respectively include storage ports S1, S2, Sn for respectively coupling to storage elements 155, 156, 157, interconnect ports I1, I2, In for coupling to interconnect 320, and host ports H1 181, H2, 180, Hn 390 for respectively coupling to hosts 370, 380, and 190. Each storage controller also includes a logic 311, 312, 313 for controlling the storage controllers 110, 120, 310 to operate as described below.

In the n-way distributed redundancy scalable network storage controller architecture 300 of the present invention, each mirror cache MC1 350, MC2 360, MCn 340 is is available to mirror any storage controller's dirty cache partition. That is, there is no longer a fixed relationship between a mirror cache and the data cache. For example, MCn 340 is not associated with a particular controller in n-way distributed redundancy scalable networked storage controller architecture 300. Similarly, MC2 360 of SC2 120 is not directly associated with DC1 130. MC2 360 is now available to mirror any other controller's cache in n-way distributed redundancy scalable networked storage controller architecture 300. MC1 350 of SC1 110 is also available to mirror any other cache in scalable n-way redundancy storage controller architecture 300.

The mirror cache partitions form a distributed mirror cache which is not confined to controller pairs. In the scalable n-way distributed redundancy scalable networked storage controller architecture 300, any controller that receives a write request may become the cache mirror for the write data. That controller then forwards the request to the controller that owns the volume requested. For example, if host 1 190 requests a write to volume 1 150 via SCn 310, SCn 310 knows that volume 1 150 belongs to SC1 110 and forwards the request there. Host 1 190 is used as an example for ease of explanation; however, it should be understood that any host coupled to the SAN may provide commands to any storage controller. SC1 110 allocates buffer space and acknowledges the write request to SCn 310. SCn 310 accepts the write data from host 1 190 and stores the write data in MCn 340. SCn 310 then copies the write data to SC1 110 via interconnect 320. SC1 110 stores the data in DC1 130 and acknowledges that the write is complete to SCn 310. SCn 310 acknowledges the write as complete to host 1 190.

In another example, host 2 370 requests a write to volume 1 150. In this case, SC1 110 allocates the buffer space, accepts the data from host 2 370, then stores the data in DC1 130. SC1 110 then forwards the request to another storage controller for mirroring.

It is important to note that once a cache mirror has been established for a particular segment of a volume, it continues to be used as the mirror for future requests until such a time as the dirty cache is flushed and the data is written to its corresponding volume. In other words, once a mirror has been established, two-way redundancy goes into effect for that particular segment of data. Therefore, n-way redundancy is advantageous only when establishing new mirrors.

The following example illustrates this point. If the write request for volume 1 150 in the previous example corresponded to the same segment of the volume that was already mirrored in SC2 120, SC1 110 would acknowledge the write request to SCn 310 after allocating buffer space. However, SC1 110 would also notify SCn 310 that another mirror already existed and that it should not store the write data in its own MCn 340. SCn 310 then would accept the write data from host 1 190 and forward it directly to SC1 110 without storing the data in MCn 340. At this point, it is the responsibility of SC1 110 to mirror the write data to SC2 120, where the mirror has already been established. The write data has now passed through interconnect 320 twice, which limits the bandwidth of interconnect 320. However, n-way distributed redundancy scalable networked storage controller architecture 300 provides a mechanism for establishing new mirrors that avoids excessive and redundant data traffic.

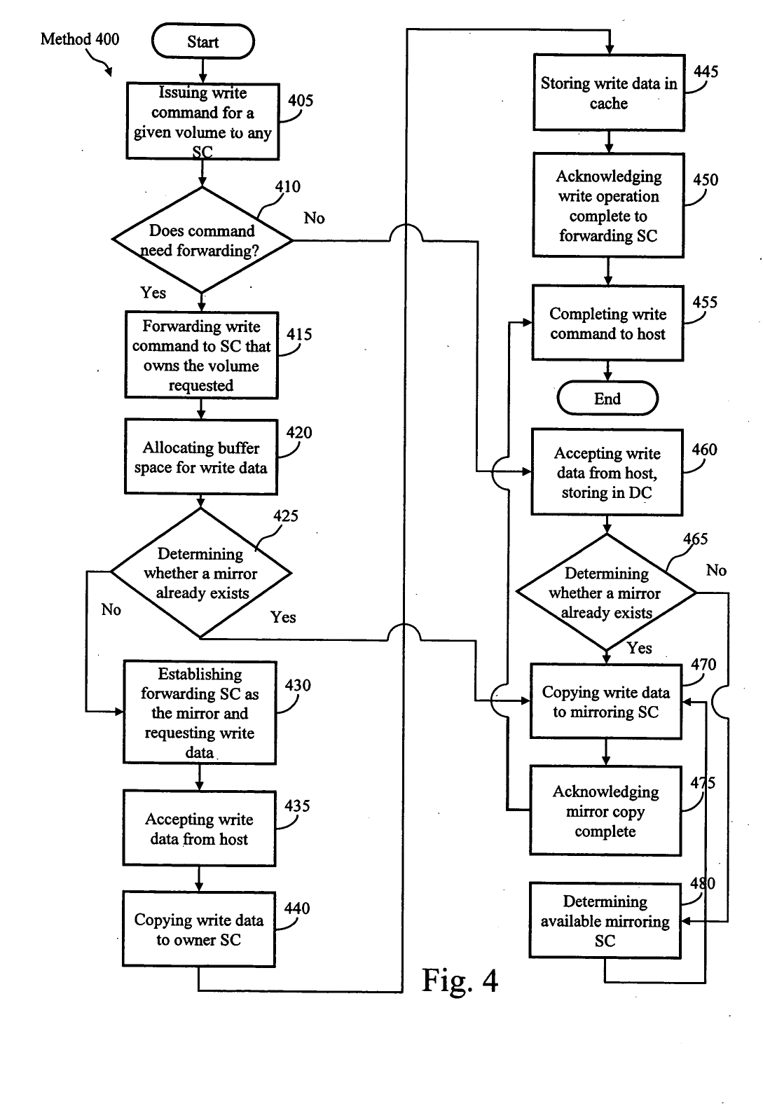

FIG. 4 illustrates a flow diagram of the method for performing a cached write operation using n-way distributed redundancy scalable networked storage controller architecture 300, previously described in FIG. 3.

Step 405:

Issuing Write Command for a Given Volume to any SC

In this step, a host issues a write command via a host port for a specific volume. Method 400 proceeds to step 410.

Step 410:

Does Command Need Forwarding?

In this step, the receiving storage controller determines whether the volume requested is one that it controls. If yes, method 400 proceeds to step 415; if no, method 400 proceeds to step 460.

Step 415:

Forwarding Write Command to SC that Owns the Volume Requested

In this step, the storage controller forwards the write command to the storage controller that is the owner of the volume requested. Method 400 proceeds to step 420.

Step 420:

Allocating Buffer Space for Write Data

In this step, the owning storage controller allocates buffer space to accept the write data from the host. Method 400 proceeds to step 425.

Step 425:

Determining Whether a Mirror Already Exists

In this step, the owning storage controller uses a lookup table to determine whether a mirror has been established for the requested volume. If yes, method 400 proceeds to step 470; if no, method 400 proceeds to step 430.

Step 430:

Establishing Forwarding SC as the Mirror and Requesting Write Data

In this step, the owning storage controller acknowledges to the forwarding storage controller that it has allocated buffer space within its resident memory for the incoming data and that it is ready to accept the data for a write operation. Method 400 proceeds to step 435.

Step 435:

Accepting Write Data from Host

In this step, the forwarding storage controller accepts the write data from the host, and stores the write data in its mirror cache. Method 400 proceeds to step 440.

Step 440:

Copying Write Data to Owner SC

In this step, the forwarding storage controller copies the write data received in step 435 to the owning storage controller via interconnect 320. Method 400 proceeds to step 445.

Step 445:

Storing Write Data in Cache

In this step, the owning storage controller stores the write data into its resident dirty cache partition. Once the dirty cache partition reaches a threshold value, the owning storage controller flushes data from the dirty cache partition and writes the data to the correct volume. Method 400 proceeds to step 450.

Step 450:

Acknowledging Write Operation Complete to Forwarding SC

In this step, the owning storage controller acknowledges to the forwarding storage controller that it received the write data and has the write data stored in cache. Method 400 proceeds to step 455.

Step 455:

Completing Write Command to Host

In this step, the forwarding storage controller sends a write complete command to the requesting host, thus completing the cached write procedure and ending method 400.

Step 460:

Accepting Write Data from Host, Storing in DC

In this step, the storage controller receiving the write command from the host is the owning storage controller. It allocates buffer space for the write data and sends an acknowledge back to the host that it is ready to receive the write data. The owning storage controller stores the write data in its resident dirty cache partition. Method 400 proceeds to step 465.

Step 465:

Determining Whether a Mirror Already Exists

In this step, the owning storage controller uses a lookup table to determine whether a mirror exists for the requested volume. If yes, method 400 proceeds to step 470; if no, method 400 proceeds to step 480.

Step 470:

Copying Write Data to Mirroring SC

In this step, the owning storage controller copies the write data to the corresponding mirror storage controller. Method 400 proceeds to step 475.

Step 475:

Acknowledging Mirror Copy Complete

In this step, the mirror storage controller acknowledges to the owning storage controller that the write data has been received and stored in mirror cache. Method 400 proceeds to step 455.

Step 480:

Determining Available Mirroring SC

In this step, the owning storage controller determines a readily accessible and available mirror storage controller for the requested volume, as none has been previously established and the owning storage controller cannot be the mirror storage controller. Method 400 proceeds to step 470.

The present invention therefore mitigates against the potential that a mirroring storage controller would be unavailable when presented with a host request through the use of n-way redundancy in combination with distributed mirror caching. With the n-way distributed redundancy scalable networked storage controller architecture of the present invention, the mirrored cache may be located in any available storage controller, provided a cache mirror has not already been established. Furthermore, write data travels over the interconnect only once from the newly established mirroring storage controller to the owning storage controller, thus eliminating excessive data traffic over the interconnect.

While the invention has been described in detail in connection with the exemplary embodiment, it should be understood that the invention is not limited to the above disclosed embodiment. Rather, the invention can be modified to incorporate any number of variations, alternations, substitutions, or equivalent arrangements not heretofore described, but which are commensurate with the spirit and scope of the invention. Accordingly, the invention is not limited by the foregoing description or drawings, but is only limited by the scope of the appended claims.

1. A storage controller system, comprising:
a plurality of storage controllers, each of said storage controllers comprising:
a host interface, for coupling with one or more hosts;
a storage interface, for coupling with at least one local storage device;
a controller interface, for coupling with other ones of said plurality of storage controllers;
a cache memory, said cache memory comprising:
a dirty cache partition; and
a mirrored cache partition, usable for storing contents of a dirty cache partition of another one of said plurality of storage controllers; and
a control logic, coupled to said host interface, said storage interface, said controller interface, and said cache memory, said control logic for dynamically creating a mirroring relationship between a dirty cache partition of a first one of said storage controllers and a mirror cache partition of a second one of said storage controllers.

2. The storage controller system of claim 1, wherein said control logic is configured to dynamically create a mirroring relationship only when said mirroring relationship would cause contents of a dirty cache partition of said first one of said storage controllers to be mirrored in exactly one mirror cache partition.

3. The storage controller system of claim 2, wherein said control logic is configured to dynamically create said mirroring relationship only when servicing a write command from a host.

4. The storage controller system of claim 1, further comprising:
an interconnection network, coupled to the controller interface of each storage controller, to permit information to be exchanged among the plurality of storage controllers.

5. The storage controller system of claim 4, wherein said control logic includes logic to forward a write command received from a host for a non-local storage device via said interconnection network to another one of said storage controllers which is local to said non-local storage device.

6. The storage controller system of claim 4, wherein said control logic includes logic for dynamically creating a mirroring relationship by forwarding a message to another one of said storage controllers via said interconnection network.

7. The storage controller system of claim 1, wherein the plurality of storage controllers is an odd number of storage controllers.

8. The storage controller system of claim 1, wherein said control logic include logic for recognizing an addition of another storage controller to said plurality of storage controllers.

9. The storage controller system of claim 1, wherein said control logic includes logic to delete said mirroring relationship when write data stored in said dirty cache partition of said first one of said storage controllers has been written to a storage device.

10. A method for operating a storage system including a plurality of storage controllers each including a dirty cache partition and a mirror cache partition, the method comprising:
receiving, at a local one of said plurality of storage controllers, a write request to a target storage device from a host;
accepting, at said local one of said plurality of storage controllers, write data from said host;
if said write request is directed to a storage device which is not coupled to said local one of said plurality of storage controllers:
forwarding said write request to a target storage controller which is local to said target storage device;
if a dirty cache partition of said target storage controller is not in a mirroring relationship with a mirror cache partition of another one of said storage controllers, establishing, by said target storage controller, said mirroring relationship between said dirty cache partition of said target storage controller and a mirror cache partition of said local one of said storage controllers; and
forwarding, by said local one of said storage controllers, write data received from said host to said target storage controllers;
if said write request is directed to a storage device which is coupled to said local one of said plurality of storage controllers:
storing, said write data in a dirty cache partition of said local one of said storage controllers;
if the dirty cache partition of said local one of said storage controllers is not in a mirroring relationship with a mirror cache partition of another one of said storage controllers, establishing, by said local one of said storage controllers, a mirroring relationship between said dirty cache partition of said local one of said storage controllers and said mirror cache partition of another one of said storage controllers; and
forwarding, by said local one of said storage controllers, write data received from said host to said another one of said storage controllers.
